(19) United States
(12) Patent Application Publication
(10) Pub. No.: US 2015/0187877 A1
(43) Pub. Date: Jul. 2, 2015

(54) POWER SEMICONDUCTOR DEVICE

(71) Applicant: SAMSUNG ELECTRO-MECHANICS CO., LTD., Suwon-Si (KR)

(72) Inventors: Jae Hoon PARK, Suwon-Si (KR); Jae Kyu SUNG, Suwon-Si (KR); In Hyuk SONG, Suwon-Si (KR); Kee Ju UM, Suwon-Si (KR); Dong Soo SEO, Suwon-Si (KR)

(73) Assignee: SAMSUNG ELECTRO-MECHANICS CO., LTD., Suwon-Si (KR)

(21) Appl. No.: 14/273,164

(22) Filed: May 8, 2014

(30) Foreign Application Priority Data
Dec. 27, 2013 (KR) 10-2013-0165427

(51) Int. Cl. H01L 29/08; H01L 29/739

(52) U.S. Cl. CPC H01L 29/0804; H01L 29/7393

(57) ABSTRACT

A power semiconductor device may include: an active region having a channel formed therein when the power semiconductor device is turned on, the channel allowing a current to flow therethrough; a termination region formed around the active region; first trenches formed in the active region, each first trench having an insulating layer formed on a surface thereof and filled with a conductive material; and second trenches formed in the termination region, each second trench having an insulating layer formed on a surface thereof and filled with a conductive material.

### CROSS-REFERENCE TO RELATED APPLICATION

This application claims the benefit of Korean Patent Application No. 10-2013-0165427 filed on Dec. 27, 2013, with the Korean Intellectual Property Office, the disclosure of which is incorporated herein by reference.

### BACKGROUND

The present disclosure relates to a power semiconductor device.

An insulated gate bipolar transistor (IGBT) is a transistor manufactured to have bipolarity by forming a gate using a metal oxide semiconductor (MOS) and forming a p-type collector layer on a rear surface thereof.

Since power metal oxide semiconductor field effect transistors (MOSFETs) were developed in the related art, these transistors have been used in fields requiring high speed switching characteristics.

However, due to inherent structural limitations of MOSFETs, bipolar transistors, thyristors, gate turn-off (GTO) thyristors, and the like, have been used in fields requiring the application of high levels of voltage thereto.

Since IGBTs have low forward loss and rapid switching speed characteristics, the application of the IGBT has increased in fields to which existing thyristors, bipolar transistors, MOSFETs and the like may not be applied.

An operational principle of an IGBT will be described. In the case in which an IGBT device is turned on, when a voltage applied to an anode is higher than a voltage applied to a cathode and a voltage higher than a threshold voltage of the IGBT is applied to a gate electrode, a polarity of a surface of a p-type body region positioned at a lower end of the gate electrode may be inverted, such that an n-type channel is formed.

An electron current injected into a drift region though the channel induces the injection of a hole current from a high-concentration p-type collector layer positioned in a lower portion of the IGBT, similar to a base current of the bipolar transistor.

Due to the injection of these minority carriers at a high concentration, a process of conductivity modulation, in which conductivity in the drift region increases by several tens to several hundreds of times, occurs.

Unlike the MOSFET, in the IGBT, a level of a resistance component in the drift region may be greatly reduced due to the process of conductivity modulation. Therefore, the IGBT may allow very high levels of voltage to be applied thereto.

Current flowing to the cathode is divided into an electron current flowing through the channel and a hole current flowing through a p-n junction between a p-type body region and an n-type drift region.

Since the IGBT has a pnp structure between the anode and the cathode in a structure of a substrate, the IGBT does not have a diode embedded therein unlike the MOSFET, and thus, a separate diode should be connected in reverse parallel with the IGBT.

The main characteristics of such an IGBT reside in maintenance of a breakdown voltage, a decrease in conduction loss, and an increase in switching speed.

According to the related art, a magnitude of voltage required in the IGBT has increased. Therefore, improved durability of the IGBT has been demanded.

Particularly, in order to maximize the conductivity modulation, a hole accumulation region may be formed below the channel.

The hole accumulation region inserted in order to improve the conduction loss of the IGBT may significantly contribute to improvement of current density, but may decrease a positive effect of p-type impurities of a p-type body region positioned at a boundary between an active region and a termination region of a power semiconductor device.

Therefore, a breakdown voltage may be lowered at the boundary between the active region and the termination region of a power semiconductor device.

The following Related Art Document (Patent Document 1), which relates to a semiconductor device having a junction structure, discloses that a peripheral region has a breakdown voltage higher than that of a cell region.

### RELATED ART DOCUMENT

(Patent Document 1) Korean Patent Laid-Open Publication No. 2006-0066655

### SUMMARY

An aspect of the present disclosure may provide a power semiconductor device having increased breakdown voltage in a termination region.

According to an aspect of the present disclosure, a power semiconductor device may include: an active region having a channel formed therein when the power semiconductor device is turned on, the channel allowing a current to flow therethrough; a termination region formed around the active region; first trenches formed in the active region, each first trench having an insulating layer formed on a surface thereof and filled with a conductive material; and second trenches formed in the termination region, each second trench having an insulating layer formed on a surface thereof and filled with a conductive material.

The second trenches may be disposed to enclose the active region.

The power semiconductor device may further include a p-type electric field limiting ring formed around the second trenches.

The second trench may have a depth greater than that of the first trench.

The power semiconductor device may further include an emitter electrode formed in an upper portion of the active region, wherein the second trench may have the same potential as the emitter electrode.

According to another aspect of the present disclosure, a power semiconductor device may include: an active region having a channel formed therein when the power semiconductor device is turned on, the channel allowing a current to flow therethrough; a termination region formed around the active region; first trenches formed in the active region, each first trench having an insulating layer formed on a surface thereof and filled with a conductive material; a first conductivity type hole accumulation region formed in the active region and formed below the channel; and second trenches formed in the termination region, each second trench having an insulating layer formed on a surface thereof and filled with a conductive material.

The second trenches may be disposed to enclose the active region.

The power semiconductor device may further include a p-type electric field limiting ring formed around the second trenches.

The second trench may have a depth greater than that of the first trench.

The power semiconductor device may further include an emitter electrode formed in an upper portion of the active region, wherein the second trench may have the same potential as the emitter electrode.

The power semiconductor device may further include an intermediate region positioned between the active region and the termination region; and a deep body region formed in the intermediate region.

The deep body region may cover a portion of the hole accumulation region.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view illustrating a portion of a power semiconductor device according to an exemplary embodiment of the present disclosure;

FIGS. 2 through 4 are schematic cross-sectional views taken along line A-A′ of FIG. 1, illustrating various examples of a power semiconductor device according to an exemplary embodiment of the present disclosure; and

FIGS. 5 through 7 are schematic cross-sectional views taken along line A-A′ of FIG. 1, illustrating various examples of a power semiconductor device including a hole accumulation region according to another exemplary embodiment of the present disclosure.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A power switch may be configured as any one of a power metal oxide semiconductor field effect transistor (MOSFET), an insulated gate bipolar transistor (IGBT), a thyristor, and devices similar thereto. Most of the new technologies disclosed herein will be described based on the IGBT. However, several exemplary embodiments of the present disclosure are not limited to the IGBT. The present inventive concept may also be applied to other types of power switch technology including power MOSFETs and several types of thyristors. Further, several exemplary embodiments of the present disclosure will be described as including specific p-type and n-type regions. However, conductivity types of several regions disclosed herein may be similarly applied to devices having conductivity types opposite thereto.

In addition, an n-type or a p-type used herein may be defined as a first conductivity type or a second conductivity type. Meanwhile, the first and second conductivity types are different types of conductivity.

In general, ‘+’ refers to a state in which a region is heavily doped and ‘−’ refers to a state in which a region is lightly doped.

For clarification, the first conductivity type will be referred to as an n-type and the second conductivity type will be referred to as a p-type, but the present disclosure is not limited thereto.

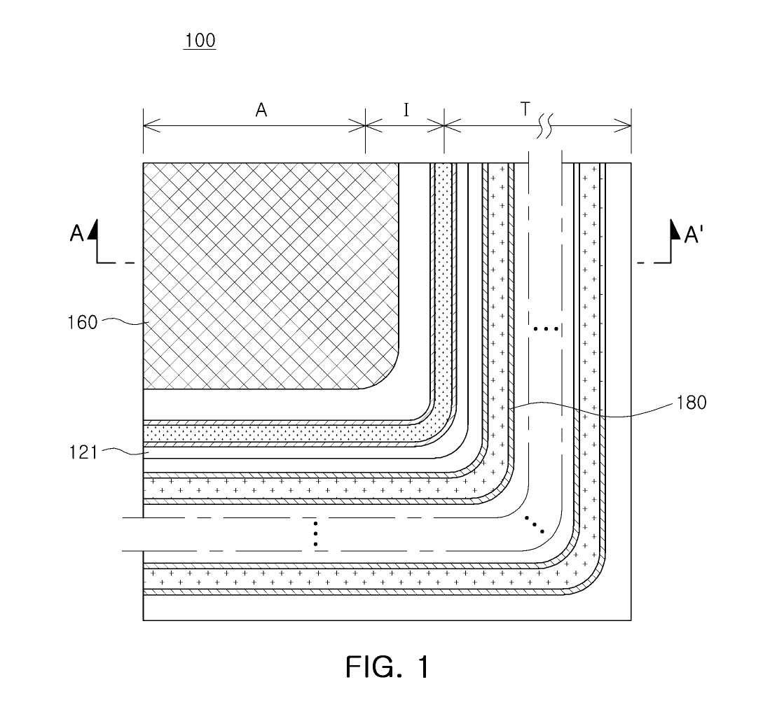

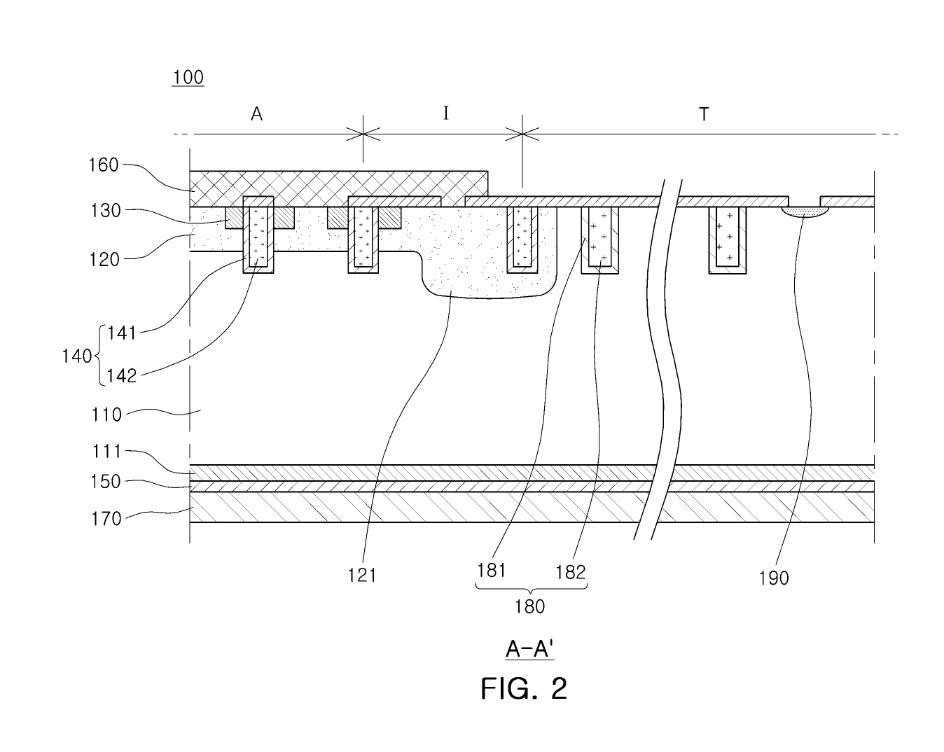

FIG. 1 is a schematic plan view of a power semiconductor device 100 according to an exemplary embodiment of the present disclosure, and FIG. 2 is a schematic cross-sectional view taken along line A-A′ of FIG. 1.

A structure of the power semiconductor device 100 according to this exemplary embodiment of the present disclosure will be described with reference to FIGS. 1 and 2.

The power semiconductor device 100 according to this exemplary embodiment of the present disclosure may include an active region A having a current flowing therein when the power semiconductor device 100 is turned on, and a termination region T formed around the active region A and supporting a breakdown voltage.

An intermediate region I may be positioned between the active region A and the termination region T.

First, a structure of the active region A will be described.

The active region A may include a drift region 110, a body region 120, an emitter region 130, and a collector region 150.

The drift region 110 may be formed by implanting n-type impurities at a low concentration.

Therefore, the drift region 110 may be relatively thick in order to maintain a breakdown voltage of the power semiconductor device.

The drift region 110 may further include a buffer region 111 formed in a lower portion thereof.

The buffer region 111 may be formed by implanting n-type impurities into the lower portion of the drift region 110.

The buffer region 111 may serve to block extension of a depletion region of the power semiconductor device at the time of the extension of the depletion region, thereby assisting in maintaining a breakdown voltage of the power semiconductor device.

Therefore, in the case in which the buffer region 111 is formed, a thickness of the drift region 110 may be decreased, such that the power semiconductor device may be miniaturized.

The body region 120 may be formed by implanting p-type impurities into an upper portion of the drift region 110.

The body region 120 may have a p-type conductivity to form a p-n junction with the drift region 110.

The emitter region 130 may be formed by implanting n-type impurities at a high concentration into an upper portion of body region 120.

First trenches 140 may be formed to extend from the emitter region 130 to the drift region 110 through the body region 120.

That is, the first trenches 140 may penetrate from the emitter region 130 into a portion of the drift region 110.

The first trenches 140 may be elongated in one direction and may be arranged at predetermined intervals in a direction perpendicular to one direction.

The first trench 140 may have a gate insulating layer 141 formed in a region in which it contacts the drift region 110, the body region 120, and the emitter region 130.

The gate insulating layer 141 may be formed of a silicon oxide (SiO₂), but is not limited thereto.

The first trench 140 may be filled with a conductive material 142.

The conductive material 142 may be a polysilicon (poly-Si) or a metal, but is not limited thereto.

The conductive material 142 may be electrically connected to a gate electrode (not shown) to control an operation of the power semiconductor device 100 according to the exemplary embodiment of the present disclosure.

In the case in which a positive voltage is applied to the conductive material 142, a channel may be formed in the body region 120.

In detail, in the case in which the positive voltage is applied to the conductive material 142, electrons present in the body region 120 may be drawn toward the trench 140 and be collected around the trench 140, thereby forming the channel.

That is, electrons and holes may be recombined with each other due to a p-n junction, such that the trench 140 draws the electrons toward a depletion region in which carriers are not present to thereby form the channel, whereby a current may flow through the channel.

The collector region 150 may be formed by implanting p-type impurities into a lower portion of the drift region 110 or the buffer region 111.

In the case in which the power semiconductor device is an IGBT, the collector region 150 may provide holes to the power semiconductor device.

Due to injection of the holes, which are minority carriers, at a high concentration, a conductivity modulation in which conductivity in the drift region is increased several tens to several hundreds of times occurs.

In the case in which the power semiconductor device is an MOSFET, the collector region 150 may have an n-type conductivity.

An emitter metal layer 160 may be formed on exposed upper surfaces of the emitter region 130 and the body region 120, and a collector metal layer 170 may be formed on a lower surface of the collector region 150. The emitter metal layer serves as an emitter electrode and the collector metal layer serves as a collector electrode.

Next, a structure of the intermediate region I will be described.

The intermediate region I may have a deep body region 121 having a second conductivity type and being deeper than the body region 120.

A portion of the top of the deep body region 121 may be electrically connected to the emitter metal layer 160 through an opening in an insulating layer.

Therefore, when the power semiconductor device 100 is turned off, some holes failing to move to the active region A may be allowed to move through the open top portion of the deep body region 121.

In addition, since the deep body region 121 is electrically connected to the emitter metal layer 160, it may serve to expand an electric field.

Therefore, the deep body region 121 reduces a possibility of occurrence of latch-up, thereby improving reliability of the power semiconductor device.

Next, a structure of the termination region T will be described.

The termination region T may have second trenches 180 formed therein.

At least a portion of the second trench 180 may be disposed within the deep body region 121 of the intermediate region I.

As shown in FIG. 1, the second trench 180 may enclose the active region A.

The second trench 180 may have a gate insulating layer 181 formed on a surface thereof and may be filled with a conductive material 182.

The second trench 180 may be electrically connected to the emitter metal layer 160 to thereby have the same potential as that of the emitter metal layer 160.

For example, in the case in which the power semiconductor device 100 is operated in a blocking mode, it may have a reference potential of 0V since the second trench 180 is connected to the emitter metal layer 160.

Therefore, in the blocking mode, an electric field in a lower portion of the second trench 180 may be expanded, whereby a breakdown voltage of the power semiconductor device may be increased.

Therefore, the power semiconductor device according to this exemplary embodiment of the present disclosure may have a reduction in area of the termination region as compared with the related art, resulting in miniaturization of a chip.

In addition, unlike the related art, since it is not necessary to provide a field plate made of a metal material or a field plate made of polycrystal silicon on the upper portion of the termination region in order to expand the electric field, the electric field of the power semiconductor device may not be affected thereby, resulting in improved reliability.

The termination region T may have an n+ field stop region 190 formed at the outermost portion thereof.

The field stop region 190 may serve to prevent the electric field from being discharged laterally from the power semiconductor device 100.

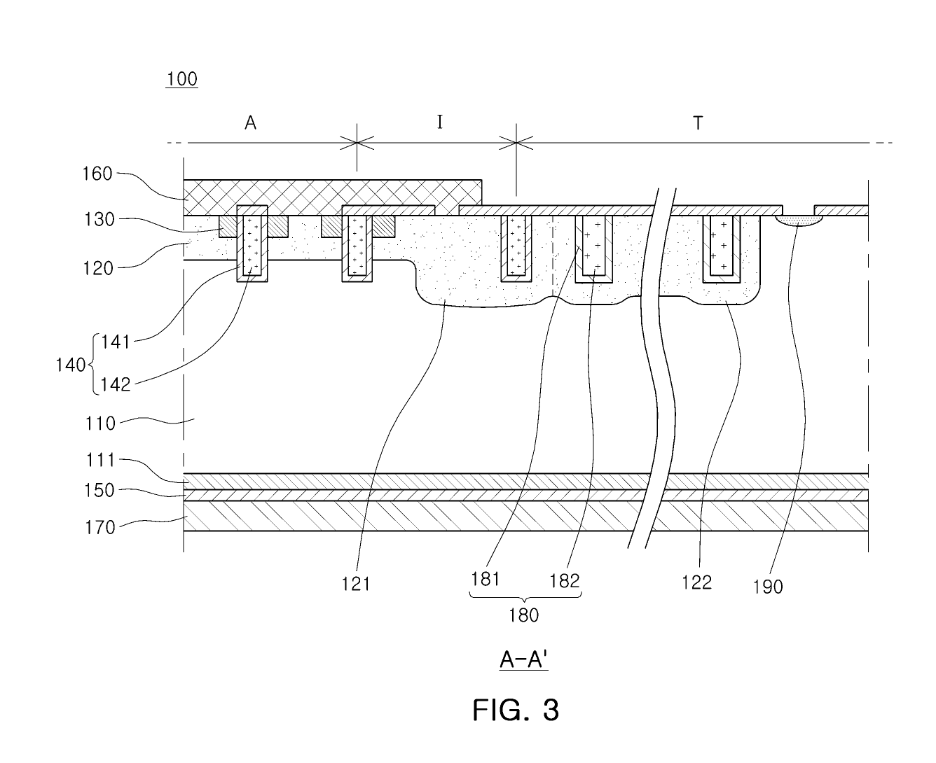

FIG. 3 is a schematic cross-sectional view of the power semiconductor device 100 further including an electric field limiting ring 122 formed around the second trench 180.

A description of elements the same as those described above will be omitted.

The electric field limiting ring 122 may be formed around at least a portion of the second trench 180 formed in the termination region T.

For example, the electric field limiting ring 122 having a p-type conductivity may be formed around the lower portion of the second trench 180.

In the case in which a trench is formed by etching, an electric field may be concentrated on the bottom of the trench due to a shape of the bottom of the trench.

In the case in which the electric field is concentrated, the breakdown voltage of the power semiconductor device 100 is sharply lowered. Therefore, the power semiconductor device 100 according to the exemplary embodiment of the present disclosure may prevent the electric field from being concentrated by forming the electric field limiting ring 122 around the second trench 180.

Therefore, the breakdown voltage of the power semiconductor device 100 may be increased.

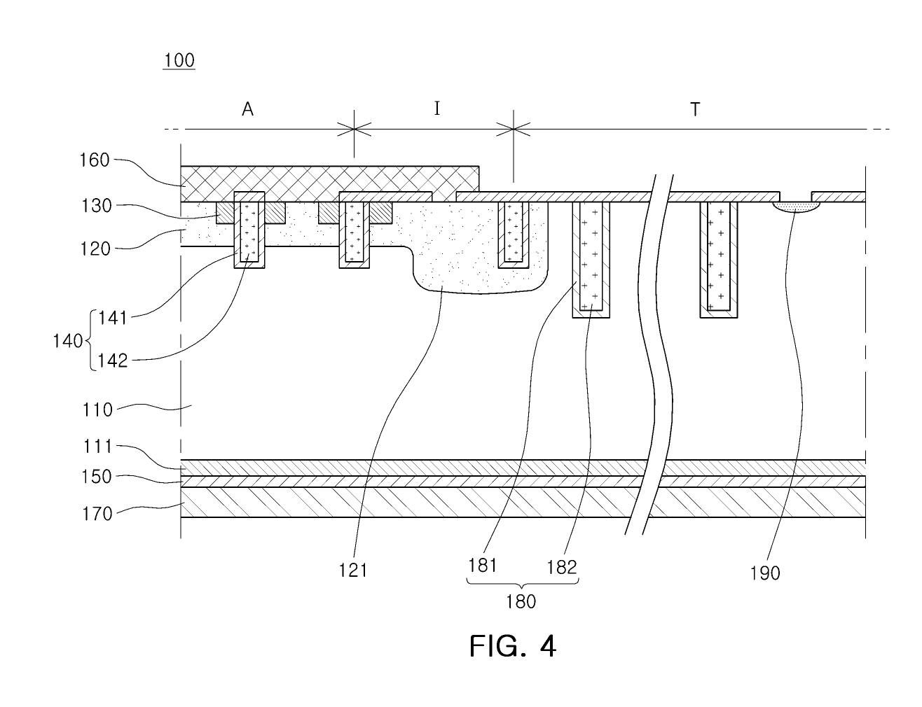

FIG. 4 is a schematic cross-sectional view of the power semiconductor device 100 in which the second trench 180 is formed to be deeper than the first trench 140.

Since the second trench 180 has a depth greater than that of the first trench 140, an electric field may be expanded in a vertical direction as well as in a horizontal direction.

In the case in which only a p-type guard ring is used as in the power semiconductor device according to the related art, it is difficult to expand an electric field in a horizontal direction due to limitations in depth and concentration of p-type impurities implanted.

However, since the power semiconductor device 100 according to the exemplary embodiment of the present disclosure may adjust the expansion of the electric field by etching the trench, it may expand the electric field in a depth direction unlike the power semiconductor device according to the related art.

Intervals between the plurality of second trenches 180 in the termination region T may be equal to or different from one another, depending on a required breakdown voltage of the power semiconductor device.

The termination region T is an essential element to maintain the breakdown voltage, but does not allow a current to directly flow therein.

Therefore, in the case in which the breakdown voltage is maintained or increased and the termination region T is significantly reduced, the power semiconductor device may be miniaturized or have high current density.

Since the power semiconductor device 100 according to this exemplary embodiment of the present disclosure may have the second trenches 180 deeper than the first trenches 140, thereby expanding the electric field in the depth direction, and thus, a width of the termination region may be decreased as compared with the related art.

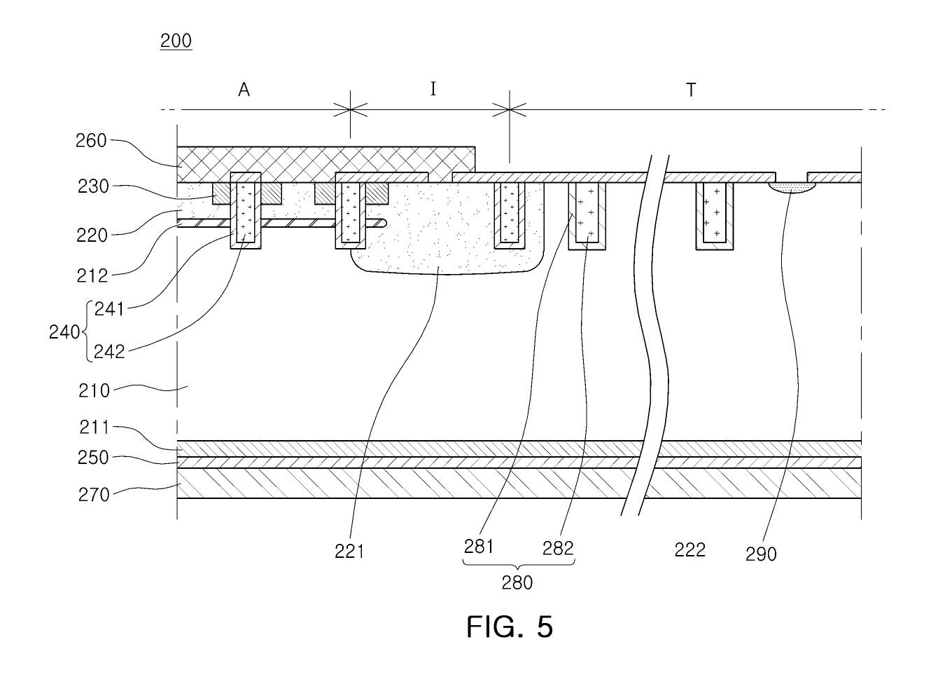

FIG. 5 is a schematic cross-sectional view of a power semiconductor device 200 including a hole accumulation region 212.

Referring to FIG. 5, the power semiconductor device 200 according to this exemplary embodiment of the present disclosure may further include the hole accumulation region 212 formed in the active region A and formed below the channel.

The hole accumulation region 212 may have a concentration of impurities higher than that of the drift region 210.

For example, the hole accumulation region 212 may be formed by implanting n+ impurities.

Since the hole accumulation region 212 is formed by implanting the n+ impurities, the holes injected from the collector region 250 may be accumulated at a lower portion of the hole accumulation region 212.

Therefore, conductivity modulation may be maximized, whereby a turn-on voltage of the power semiconductor device may be lowered.

Since the hole accumulation region 212 is formed by implanting the n+ impurities, in the case in which the breakdown voltage is maintained by using only a p-type guard ring as in the related art, the effect of the guard ring may be relatively decreased and the breakdown voltage may be lowered.

However, since the power semiconductor device according to the exemplary embodiment of the present disclosure maintains the breakdown voltage using second trenches 280, it may prevent the breakdown voltage from being lowered and may maintain a high breakdown voltage even in the case in which the hole accumulation region 212 is formed.

As described above, the power semiconductor device may further include the intermediate region I positioned between the active region A and the termination region T and may further include a deep body region 221 formed in the intermediate region I.

The deep body region 221 may cover a portion of the hole accumulation region 212.

In the case in which the hoe accumulation region 212 is formed, when the hole accumulation region 212 directly contacts the drift region 210 in the intermediate region I, the electric field may concentrate on the corresponding portion.

That is, in the case in which the hole accumulation region 212 directly contacts the drift region 210, the electric field concentrates on the bottom of a first trench 240 disposed in contact with the intermediate region I among the first trenches 240, resulting in a decrease in breakdown voltage.

Therefore, the deep body region 221 covers at least a portion of the bottom of the first trench 240 disposed in contact with the intermediate region I, whereby the breakdown voltage may be increased.

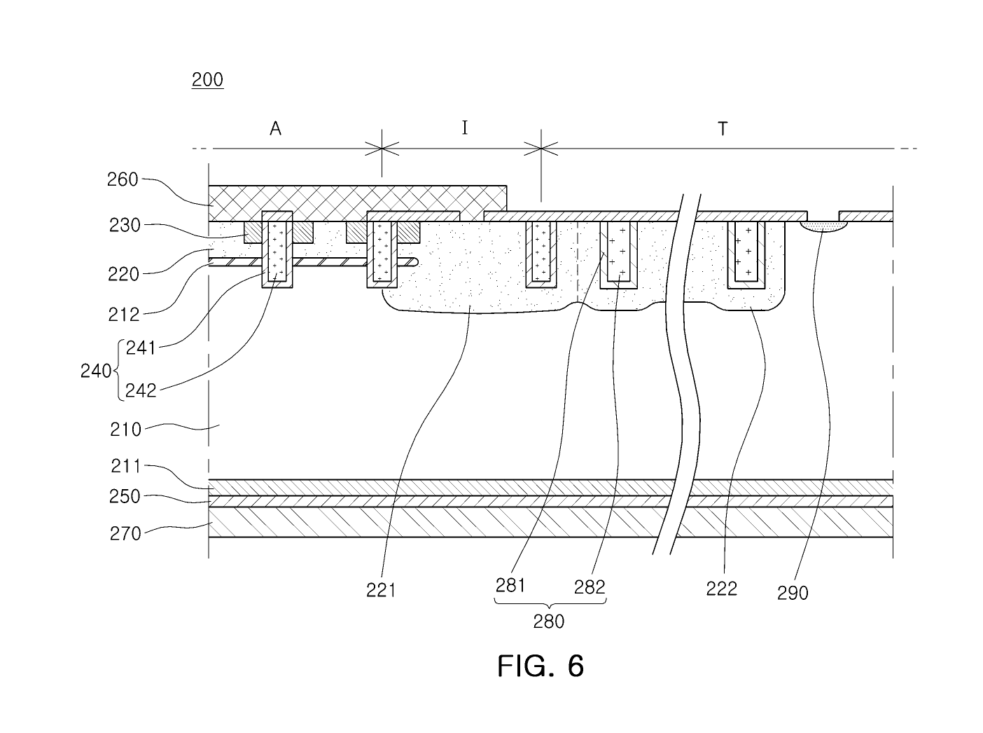

FIG. 6 is a schematic cross-sectional view of the power semiconductor device 200 further including an electric field limiting ring 222 formed around second trenches 280.

The electric field limiting ring 222 may be formed around at least a portion of the second trenches 280 disposed in the termination region T.

For example, the electric field limiting ring 222 having a p-type conductivity may be formed around a lower portion of the second trench 280.

In the case in which a trench is formed by etching, an electric field may be concentrated on the bottom of the trench due to a shape of the bottom of the trench.

In the case in which the electric field is concentrated, the breakdown voltage of the power semiconductor device 200 is sharply lowered. Therefore, the power semiconductor device 200 according to the exemplary embodiment of the present disclosure may prevent the electric field from being concentrated by forming the electric field limiting ring 222 around the second trench 180.

Therefore, the breakdown voltage of the power semiconductor device 200 may be increased.

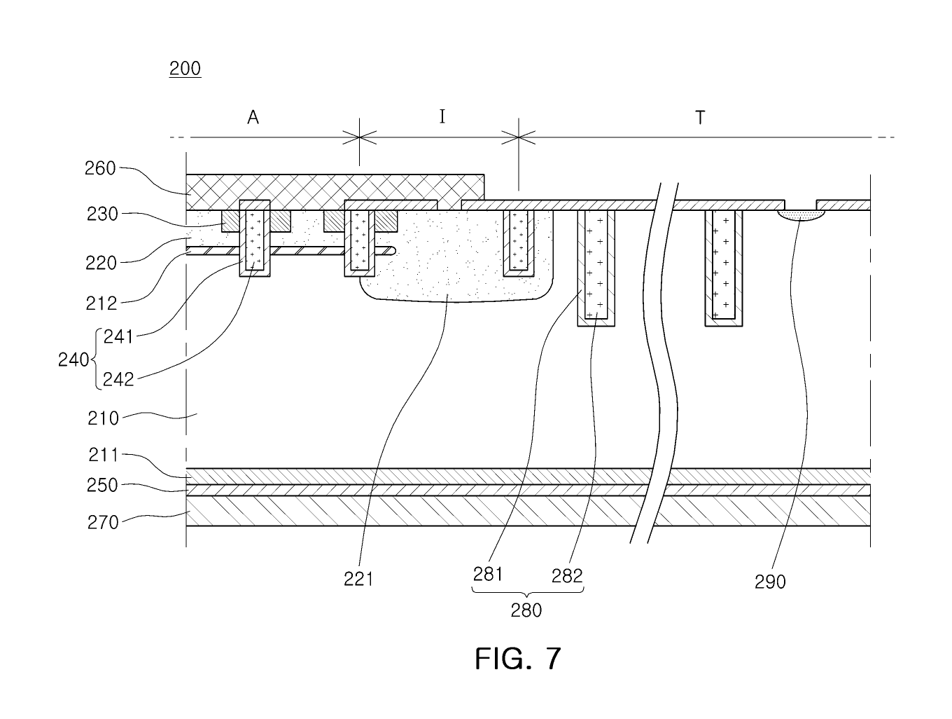

FIG. 7 is a schematic cross-sectional view of the power semiconductor device 200 in which the second trench 280 is deeper than the first trench 240.

Since the second trench 280 may have a depth greater than that of the first trench 240, an electric field may be expanded in a vertical direction as well as a horizontal direction.

In the case in which only a p-type guard ring is used as in a power semiconductor device according to the related art, it is difficult to expand an electric field in a horizontal direction due to limitations in depth and concentration of p-type impurities implanted.

However, since the power semiconductor device 200 according to the exemplary embodiment of the present disclosure may adjust the expansion of the electric field by etching the trench, it may expand the electric field in a depth direction unlike the power semiconductor device according to the related art.

The termination region T is an essential element to maintain the breakdown voltage, but does not allow a current to directly flow therein.

Therefore, in the case in which the breakdown voltage is maintained or increased and the termination region T is significantly reduced, the power semiconductor device may be miniaturized or have high current density.

Since the power semiconductor device 200 according to the exemplary embodiment of the present disclosure may have the second trenches 280 deeper than the first trenches 240, thereby expanding the electric field in the depth direction, and thus, a width of the termination region may be decreased as compared with the related art.

As set forth above, according to exemplary embodiments of the present disclosure, a power semiconductor device may increase a breakdown voltage of a termination region by forming second trenches in the termination region.

In addition, in the power semiconductor device according to the exemplary embodiments of the present disclosure, since an emitter electrode and a conductive material of the second trench have the same potential in a blocking mode, the breakdown voltage of the termination region may be increased by expanding an electric field of the bottom of the second trench.

Further, in the power semiconductor device according to the exemplary embodiments of the present disclosure, an electric field limiting ring is formed around the second trench, thereby preventing the electric field from being concentrated on the bottom of the second trench and preventing the breakdown voltage from being lowered.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device, comprising:
an active region having a channel formed therein when the power semiconductor device is turned on, the channel allowing a current to flow through the active region;
a termination region formed around the active region;
first trenches formed in the active region, each first trench having an insulating layer formed on a surface thereof and filled with a conductive material; and
second trenches formed in the termination region, each second trench having an insulating layer formed on a surface thereof and filled with a conductive material.

2. The power semiconductor device of claim 1, wherein the second trenches are disposed to enclose the active region.

3. The power semiconductor device of claim 1, further comprising a p-type electric field limiting ring formed around the second trenches.

4. The power semiconductor device of claim 1, wherein the second trench has a depth greater than that of the first trench.

5. The power semiconductor device of claim 1, further comprising an emitter electrode formed in an upper portion of the active region,
wherein the second trench has the same potential as the emitter electrode.

6. A power semiconductor device, comprising:
an active region having a channel formed therein when the power semiconductor device is turned on, the channel allowing a current to flow therethrough;
a termination region formed around the active region;
first trenches formed in the active region, each first trench having an insulating layer formed on a surface thereof and filled with a conductive material;
a first conductivity type hole accumulation region formed in the active region and formed below the channel; and
second trenches formed in the termination region, each second trench having an insulating layer formed on a surface thereof and filled with a conductive material.

7. The power semiconductor device of claim 6, wherein the second trenches are disposed to enclose the active region.

8. The power semiconductor device of claim 6, further comprising a p-type electric field limiting ring formed around the second trenches.

9. The power semiconductor device of claim 6, wherein the second trench has a depth greater than that of the first trench.

10. The power semiconductor device of claim 6, further comprising an emitter electrode formed in an upper portion of the active region,
wherein the second trench has the same potential as the emitter electrode.

11. The power semiconductor device of claim 6, further comprising:
an intermediate region positioned between the active region and the termination region; and
a deep body region formed in the intermediate region.

12. The power semiconductor device of claim 11, wherein the deep body region covers a portion of the hole accumulation region.
